(19) United States
(12) Patent Application Publication
(10) Pub. No.: US 2025/0149473 A1
(43) Pub. Date: May 8, 2025

(54) RF ABSORBING COVER INTEGRATED IN MMIC PACKAGES

(71) Applicant: Qorvo US, Inc., Greensboro, NC (US)

(72) Inventors: Soack-Dae Yoon, Torrance, CA (US); Eric Jackson, Moorpark, CA (US)

(21) Appl. No.: 18/929,272

(22) Filed: Oct. 28, 2024

Related U.S. Application Data
(60) Provisional application No. 63/595,983, filed on Nov. 3, 2023.

(51) Int. Cl. H01L 23/66; H01L 23/495; H01L 23/552

(52) U.S. Cl. CPC H01L 23/66; H01L 23/49524; H01L 23/552

(57) ABSTRACT

A radio frequency (RF) module includes a circuit board, at least one integrated circuit disposed on a top surface of the circuit board, an RF absorbing cover housing the at least one integrated circuit, and a metal lid disposed above the RF absorbing cover. A first cavity is formed between the at least one integrated circuit and the RF absorbing cover. A second cavity is formed between the RF absorbing cover and the metal lid.

### RELATED APPLICATIONS

This application claims priority to U.S. Provisional Patent Application No. 63/595,983, filed Nov. 3, 2023, which is incorporated by reference herein in its entirety.

### FIELD OF THE INVENTION

The technology disclosed herein relates generally to radio frequency (RF) absorbers, and more specifically to covers made from RF absorbing material designed for absorption of electromagnetic energy emitted from one or more circuit components within monolithic microwave integrated circuit (MMIC) packages.

### BACKGROUND

Radio frequency absorbers are utilized in a variety of applications with the aim of absorbing, attenuating, scattering, or otherwise modifying radio frequency signals incident upon a surface. These absorbers find use in integrated circuit devices, antennas, and objects with radar cross-sections that are subject to radar detection, among other surfaces vulnerable to electromagnetic radiation.

To illustrate, consider circuit devices in which integrated circuit chips are housed within an enclosure (housing). This enclosure typically includes walls and a lid made of metallic material to shield against electromagnetic energy from radio frequency signals. Alternatively, the enclosure may feature walls and a lid made of non-metallic materials, such as plastic or ceramic. In either implementation, radio frequency absorbers, often in sheet form, may be additionally affixed to the interior side of the lid facing the integrated circuit chips. While such arrangements can be effective at operating frequencies below 20 GHz, their performance is generally inadequate at higher frequencies, such as millimeter-wave (mm-wave) frequencies exceeding 30 GHz. At these elevated frequencies, current implementations of radio frequency absorbers become less effective at absorption and often fail to sufficiently reduce cavity modes and resonances within the metallic enclosure.

### SUMMARY

Example aspects of the present disclosure provide an RF absorbing cover integrated into an MMIC package, bringing forth substantial enhancements in the MMIC module's performance. By significantly improving RF isolation between RF components, the RF absorbing cover ensures that each module functions without undue interference from adjacent components. Additionally, this integration effectively reduces RF interferences, thereby preventing potential signal degradation and RF instability. Such optimization not only safeguards clearer signal pathways but also boosts the MMIC package's overall reliability and efficiency. Consequently, the inclusion of an RF absorbing cover provides a viable solution for the compact and high-power module especially for mm-wave applications.

In one aspect, a radio frequency (RF) module includes a circuit board, at least one integrated circuit disposed on a top surface of the circuit board, an RF absorbing cover housing the at least one integrated circuit, thereby forming a first cavity between the at least one integrated circuit and the RF absorbing cover, and a metal lid disposed above the RF absorbing cover, thereby forming a second cavity between the RF absorbing cover and the metal lid. In some instances, the RF absorbing cover includes a magnetic loss tangent greater than 0.174. In some instances, the RF absorbing cover is free of direct contact with the metal lid. In some instances, the RF absorbing cover includes sidewalls and a lid, and the sidewalls are in direct contact with the top surface of the circuit board. In some instances, the circuit board includes signal traces fed to the at least one integrated circuit, and the sidewalls of the RF absorbing cover included at least one opening for the signal traces to travel through. In some instances, the RF absorbing cover includes a plastic material uniformly mixed with ferrite particles. In some instances, the plastic material is a high-temperature plastic material with a melting point above 200° C. In some instances, the ferrite particles are hexagonal Ba-based or hexagonal SR-based ferrite particles. In some instances, the RF absorbing cover houses two monolithic microwave integrated circuit (MMIC) chips. In some instances, the second cavity has a larger volume than the first cavity.

In another aspect, a monolithic microwave integrated circuit (MMIC) package includes a circuit board, a first MMIC bare die surface mounted on the circuit board, a second MMIC bare die surface mounted on the circuit board, a three-dimensional (3D) radiation absorbing cover partially enclosing the first and second MMIC bare dies, the radiation absorbing cover being configured to absorb radiation from the first and second MMIC bare dies, and a device housing including a base and a metal lid, the metal lid being suspended above the radiation absorbing cover. In some instances, the first and second MMIC bare dies are power amplifying integrated circuits. In some instances, a magnetic loss tangent of the radiation absorbing cover is greater than 0.174. In some instances, the radiation absorbing cover includes a plastic material uniformly mixed with a radiation absorbing material. In some instances, a volumetric percentage of the radiation absorbing material in the radiation absorbing cover is greater than 75%. In some instances, the radiation absorbing material is selected from the group of ferrite particles, carbon particles, and nanotubes. In some instances, the radiation absorbing cover has a first height, a ratio of the first height and a distance between the metal lid and the circuit board ranges from ⅕ to ½.

In another aspect, an integrated circuit package includes a circuit board, a bare die landing on the circuit board, capacitors landing on the circuit board and coupled to the bare die, leads attached to the circuit board, and a radiation absorbing cover enclosing the circuit board and the bare die, the radiation absorbing cover including sidewall openings for the leads to travel through. In some instances, a magnetic loss tangent of the radiation absorbing cover is greater than 0.174. In some instances, the integrated circuit package further includes a metal housing enclosing the radiation absorbing cover, the metal housing including a lid that is spaced apart from the radiation absorbing cover.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWINGS

The accompanying drawing figures incorporated in and forming a part of this specification illustrate several aspects of the disclosure, and together with the description, serve to explain the principles of the disclosure.

FIG. 1A illustrates a cross-sectional view of a monolithic microwave integrated circuit (MMIC) package with an MMIC chip housed in a metallic enclosure.

FIG. 1B illustrates a cross-sectional view of an MMIC package with an MMIC chip housed in a metallic enclosure with a radio frequency (RF) absorber in sheet form affixed to a lid of the metallic enclosure.

FIGS. 2A and 2B illustrate perspective and layout views, respectively, of an MMIC package that houses two MMIC chips within a metallic enclosure, in which the two MMIC chips are situated beneath a cover made from RF absorbers, according to some aspects of the present disclosure.

FIG. 3 illustrates simulated RF responses of trace under the cover as shown in FIGS. 2A and 2B, according to some aspects of the present disclosure.

FIGS. 4A and 4B illustrate perspective and layout views, respectively, of an MMIC package that houses a single MMIC chip under a cover made from RF absorbers, according to some aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected”, “operably connected”, “coupled”, “operably coupled” or “electrically coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re described.

Monolithic microwave integrated circuits (MMICs) represent a specialized class of integrated circuits designed to operate at microwave frequencies, typically ranging from 2 GHz to 300 GHz. Unlike conventional integrated circuits that primarily deal with low-frequency analog or digital signals, MMICs are engineered to handle the unique challenges posed by high-frequency microwave signals, such as millimeter-wave (mm-wave) signals. They are widely employed in applications such as radar systems, satellite communications, cellular networks, and even in medical devices for applications like imaging.

Constructed from semiconductor materials like gallium nitride (GaN), gallium arsenide (GaAs), indium phosphide (InP), silicon-germanium (SiGe), or silicon (Si), MMICs offer significant advantages in terms of speed, performance, and miniaturization. The monolithic architecture allows for the integration of multiple microwave functions, including amplifiers, mixers, oscillators, and filters, onto a single semiconductor substrate. This high level of integration results in compact circuit designs that are highly reliable and cost-effective to manufacture.

One of the primary advantages of MMICs is their capacity for excellent power efficiency, crucial in battery-operated devices like mobile phones and other portable wireless gadgets. The ability to function effectively at high frequencies while minimizing power loss and thermal effects makes them ideal for applications where both performance and energy efficiency are critical.

Another advantage of MMICs lies in their inherent capacity for high repeatability and reliability. Given that the entire circuitry is fabricated on a single semiconductor wafer, variations in component characteristics are minimized, leading to consistent performance across multiple units. This is especially important in military and aerospace applications where reliability can be critical.

Yet another advantage of MMICs becomes apparent in the realm of high-power RF and mm-wave amplifier modules, which necessitate both high RF signal production across broad frequency ranges and low-profile designs. Contemporary RF power amplifier driver modules exemplify this trend, featuring a cohesive assembly of multiple high-power RF MMIC amplifiers, along with other active components like attenuators, switches, and phase shifters. These modules also incorporate the necessary DC circuits for operational control. The ability of MMICs to accommodate such a diverse array of functions within a singular, compact package unit significantly enhances the spatial efficiency of these amplifier modules, making them highly integrated and ideal for applications requiring minimized footprint.

However, MMICs are not without their challenges. At higher frequencies, they are susceptible to problems like signal loss, interference, and increased complexity in circuit design. Moreover, the need for shielding against RF signal interference becomes increasingly critical at these elevated frequencies.

For example, RF stability is a well-recognized issue in MMIC modules, primarily due to RF signal interference between the components. This interference can conflict with design requirements, leading to significant challenges. Specifically, the high-intensity RF signals emitted by MMIC High Power Amplifiers (HPAs) are prone to radiate or couple with one another. This can cause interference and lead to potentially catastrophic RF instabilities and oscillations. Low-level oscillations may result in reduced RF output power, while severe cases could cause damage to the MMIC HPA.

To tackle this issue, one possible solution is the use of a package to shield radiated RF signals from MMIC HPAs, thereby enhancing isolation among the module's RF components. This setup also offers added physical protection for an open MMIC HPA bare die. However, there are few effective MMIC package designs specifically for MMIC HPAs operating at mm-wave frequencies above 30 GHz. Conventional packages for frequencies below 20 GHz may not be adequate for mm-wave frequencies above 30 GHz. These traditional packages generally feature one or more MMIC HPA bare dies underneath a metal lid. However, such designs have exhibited significant degradation in output power performance and even generate cavity modes within the module housing.

In the context of MMIC packages, “cavity mode” refers to resonant electromagnetic oscillations that can occur within the metallic housing designed to shield the device. Although intended to block external electromagnetic interference, the housing can inadvertently trap electromagnetic energy, creating resonant conditions at specific frequencies. These cavity modes present a host of challenges. Firstly, they can distort the electromagnetic field distribution within the package, causing inefficiencies and compromising RF (Radio Frequency) and microwave signal performance. Secondly, the resonant activity can establish feedback loops that lead to RF instabilities, making the MMIC device unreliable and unpredictable in operation. Thirdly, these modes can corrupt signal integrity by causing phase errors and amplitude fluctuations, thereby lowering the signal-to-noise ratio and degrading overall system performance. In addition, the resonant activity can create localized hotspots within the package, affecting thermal stability and potentially reducing the device's longevity. In extreme cases, particularly at high power levels, these resonant conditions can even damage sensitive MMIC components, such as MMIC HPA. Therefore, managing or suppressing cavity modes is critical for maintaining optimal performance and long-term reliability of MMIC devices.

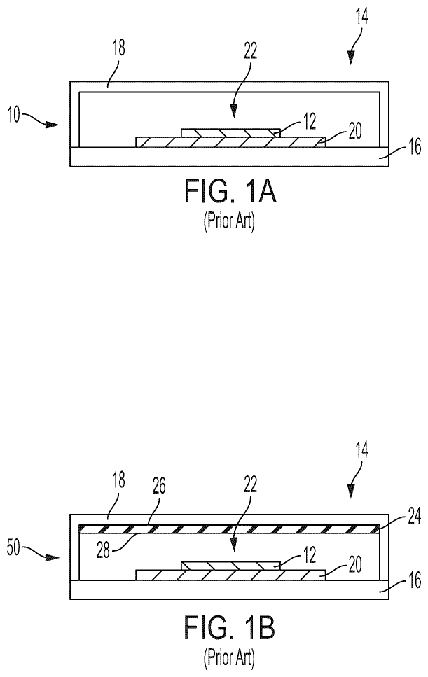

FIG. 1A shows an example of a prior art integrated circuit device 10 that houses an MMIC chip 12. The device 10 may include a device housing 14 that includes a base 16 and a lid 18 configured to enclose the MMIC chip 12 within the device 10. The base 16 is configured to support an active surface 20. The active surface 20 may be part of a printed circuit board (PCB) or a printed wiring board (PWB). The MMIC chip 12 is disposed within and/or proximate to the active surface 20. A device cavity 22 is formed within the device 10, and is configured to be the space between the lid 18 and the MMIC chip 12, within the device housing 14. The MMIC chip 12 may operate at various frequencies in the microwave range of the electromagnetic spectrum, for example, from 3 GHz to more than 100 GHz. For example, the MMIC chip 12 may operate at frequencies greater than 30 GHz.

In some applications, the integrated circuit device 10 is configured to amplify RF signals to a desired level, and the MMIC chip 12 is an RF amplifier. When the MMIC chip 12 is located within the device cavity 22 and the RF signals are applied to the MMIC chip 12, frequency oscillations, cavity resonances, and/or cavity modes may occur within the cavity. Such oscillations, together with undesirable cavity resonances may lead to irregular gain, irregular power performance, and other undesirable effects. For example, the device housing 14 may be constructed from metal. Electromagnetic energy within the cavity 22 will reflect off the metal device housing 14 and interfere with the operation of the MMIC chip 12.

Therefore, there is a need to use an RF absorber in some applications to absorb, attenuate, scatter and/or otherwise modify the electromagnetic energy within the cavity in a device housing. Such modification of the electromagnetic energy aids in increasing the effectiveness of the performance of an MMIC chip within the device housing.

FIG. 1B shows another example of a prior art integrated circuit device 50 that houses the MMIC chip 12. The various components of the integrated circuit device 50 are similar to what have been discussed above with reference to the integrated circuit device 10 in FIG. 1A. The device 50 may include the device housing 14 that includes the base 16 and the lid 18 configured to enclose the MMIC chip 12 within the device 50. The base 16 is configured to support the active surface 20. The active surface 20 may be part of a printed circuit board (PCB) or a printed wiring board (PWB). The MMIC chip 12 is disposed within and/or proximate to the active surface 20. Once difference between the device 50 and the device 10 is that the device 50 further includes an RF absorber 24 in the form of a sheet affixed to the lid 18 within the device housing 14. Accordingly, the device cavity 22 is formed within the device 50, and is configured to be the space between the RF absorber 24 and the MMIC chip 12, within the device housing 14.

The RF absorber 24 is disposed within the lid 18 and is configured to be opposing the active surface 20 and the MMIC chip 12. The RF absorber 24 includes an attachment surface 26 and an absorbing surface 28. The attachment surface 26 is configured to be proximate to and connected to the lid 18, and the absorbing surface 28 is configured to be facing the MMIC chip 12. The absorbing surface 28 is located a certain distance from the MMIC chip 12 in order to aid in minimizing loss to the normal power and gain of the MMIC chip 12. The RF absorber 24 is configured to have a thickness depending on the operating frequency of the MMIC chip 12 and other operating parameters. For example, according to one embodiment, where the distance between the MMIC chip 12 and the lid 18 is 40 mils, the RF absorber 24 may be 20 mils thick, and the distance between the absorbing surface 28 and the MMIC chip 12 is 20 mils.

Although the use of an RF absorber in the form of a sheet presents some benefits, it also presents challenges, especially at higher frequencies above 30 GHz. As the frequency rises above 30 GHz, the wavelength of the signals becomes significantly shorter. This makes the precise positioning of the RF absorber with respect to the MMIC chip critical for optimal performance. The fixed distance, dictated by the height of the cavity 22, between the RF absorber 24 and the MMIC chip 12 can pose limitations. At these higher frequencies, a fixed spacing might not be the most optimal distance for maximum absorption, thus reducing the effectiveness of the RF absorber 24. Moreover, having the sheet adhered to the lid 18 reduces flexibility in adjusting this distance for different frequency bands, potentially leading to reduced adaptability across various applications. Additionally, any minor inconsistencies or imperfections in the sheet's attachment could exacerbate signal reflection or create unwanted resonances at these higher frequencies. Consequently, while the sheet-based RF absorber design might be suitable for some applications, it may not offer the flexibility and performance optimization required for advanced systems operating at frequencies above 30 GHz.

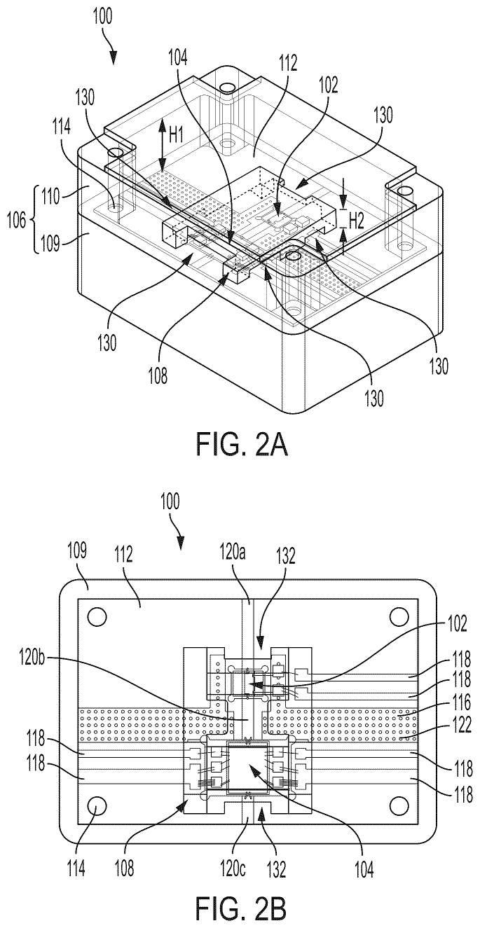

Reference is now made to FIGS. 2A and 2B, collectively. FIGS. 2A and 2B illustrate perspective and layout views, respectively, of various electronic components and MMIC chips of an MMIC device (or MMIC package) 100, according to some embodiments of the present disclosure.

In the illustrated embodiment, the MMIC device 100 houses two MMIC chips 102 and 104 within a device housing 106, in which the two MMIC chips 102 and 104 are situated beneath a cover 108 made from RF absorbing materials. The cover 108 may also be referred to as an RF absorbing cover 108 in the context. It is noted that two MMIC chips 102 and 104 are illustrated as under the cover 108, which is for illustrative purposes only and not intended to be limiting beyond what is specifically recited in the claims. It can be appreciated that any number of MMIC chips may be disposed under the cover 108, such as a single MMIC chip, three MMIC chips, or more than three MMIC chips. The MMIC chips 102 and 104 may be in the form of bare dies (e.g., as after being diced from a wafer) in some instances, or in chip-level packages in some other instances.

The device housing 106 includes a base 109 and a lid 110 configured to enclose an RF board 112 within the device housing 106. In some embodiments, both the base 109 and the lid 110 are made of metal. In some other embodiments, the base 109 and the top cover of the lid 110 are made of metal, while sidewalls of the lid 110 are made of plastic. The base 109 can be designed with a precisely contoured groove or recess that matches the dimensions and shape of the RF board 112. This groove ensures that the RF board 112 sits snugly and securely within the base 109. The depth of the groove is usually just enough to accommodate the thickness of the RF board 112, ensuring that the RF board 112 is level with or slightly below the top surface of the base 109. This configuration not only aids in holding the RF board 112 in place but also facilitates the seamless attachment of the lid 110 on top, ensuring a tight seal. The use of grooves or recesses can also assist in isolating certain components, preventing them from making unwanted contact with other parts and providing an added layer of protection against external factors.

Further, the RF board 112 may provide screw holes 114 at its four corners for the screws to travel through. The screws serve to mechanically secure the lid 110 and the RF board 112 to the base 109. By fastening the lid 110 using these screws, a tight and secure seal is achieved between the lid 110 and the base 109, ensuring that the internal components, like the RF board 112, are adequately fixed. The use of screws at the corners provides an even distribution of pressure when the lid 110 is fastened, preventing warping or misalignment. Furthermore, this configuration of attachment allows for easy access to the interior of the package if maintenance or adjustments are required, as the lid 110 can be readily removed and reattached.

In some embodiments, the RF board 112 is a printed circuit board (PCB), particularly, a soft PCB with a low dielectric constant (also referred to as low dielectric soft PCB). The term “soft” typically indicates that the PCB is flexible, made from pliable materials such as polyimide or other flexible laminates, as opposed to the rigid materials commonly found in standard PCBs. One of the advantages of utilizing a soft PCB, for MMIC applications, is providing flexibility such that the PCB can conform to non-standard shapes or be integrated into systems where a rigid board might not fit. The pliable nature of the soft PCB also provides inherent resistance to mechanical stress, reducing the risk of damage due to bending or torsional forces. One of the advantages of utilizing a low dielectric material in a PCB design is the reduction in signal loss, especially at high frequencies. A lower dielectric constant means that the material is less polarizable and will generate less parasitic capacitance. This characteristic is important for MMIC module designs, where high-frequency signals are prevalent, and any loss or distortion can significantly affect performance.

In one particular example, the RF board 112 (with DC circuitry) is formed from a glass microfiber reinforced PTFE composite, such as the high-frequency laminate produced by Rogers Corporation, known as RT/Duroid® 5870/5880 (or others like PCB from Taconic, Dupont, etc.). Engineered precisely for stripline and microstrip circuits, this board may offer low electrical loss, consistent electrical properties across diverse frequencies, minimal moisture absorption, and chemical durability. It also exhibits isotropic characteristics. The board may be conveniently shaped and is typically presented as a laminate, featuring an electrode deposited metal layer on both its surfaces. Metal layer thickness can range, but it is commonly between one-fourth to two ounces per square foot (8-70 micrometer) on both sides. These metal layers can be constructed and clad using rolled copper foil, though various metals such as aluminum, copper, or brass can be employed for cladding. Typically, a dielectric is sandwiched between these metal layers. While the boards can have a standard thickness, starting at 0.005 inches (0.127 mm), larger sizes can reach up to 0.125 inches in thickness.

The metal layer (e.g., a copper layer) on the top surface of the RF board 112 may be etched to form the ground plane 116, DC signal traces 118, and RF microstrip lines 120 (including lines 120a, 120b, 120c). The etched surface removes the copper clad and exposes the dielectric material of the RF board 112. Ground vias 122 are used throughout the ground plane 116 to provide good grounding and improve isolation. The spacing between the ground vias 122, which may be around ¼ of a wavelength of the highest operational frequency, improves isolation between different components. Each of the RF microstrip lines 120 may have a 50 Ohm impedance. Particularly, the RF microstrip line 120a transmits an RF signal received from outside of the MMIC device 100 to the input port of the MMIC chip 102, the RF microstrip line 120b transmits the pre-amplified RF signal from the output port of the MMIC chip 102 to the input port of the MMIC chip 104 for further amplification, and the RF microstrip line 120c transmits the amplified RF signal from the output port of the MMIC chip 104 to external circuits positioned in the next stage of the signal chain.

In some embodiments, the MMIC device 100 is an RF power amplifier module that includes the MMIC chip 102, which is a driver MMIC as an initial stage of the RF power amplifier module, and the MMIC chip 104, which is a high-power amplifier (HPA) MMIC as a subsequent stage of the RF power amplifier module. In furtherance of the embodiments, the MMIC chip 102 as the driver MMIC may be Qorvo's QPA2225D, and the MMIC chip 104 as the HPA MMIC may be Qorvo's TGA2222D.

Qorvo's QPA2225D is a wide band MMIC driver amplifier fabricated on Qorvo's production 0.15 um GaN on SiC process (QGaN15). The QPA2225D provides greater than 0.4 W of saturated output power with greater than 23 dB of small-signal gain. The QPA2225D has DC blocking capacitors on both RF ports, which are matched to 50 ohms. The QPA2225D can support a variety of operating conditions and a range of bias voltages to best support system requirements. In the illustrated example, two DC signal traces 118 are connected to one side of the QPA2225D. One of the two DC signal traces 118 supplies the drain voltage V_{D}, while the other one of the two DC signal traces 118 provides the gate voltage V_{G}. The QPA2225D may be a bare die surface mounted on a thermal spreader tab. Thermal vias under the thermal spreader tab carries the heat generated from the QPA2225D to the larger ground plane at the backside of the RF board 112. In some embodiments, the thermal spreader tab is made of copper-molybdenum (CuMo), which exhibits high thermal conductivity and a coefficient of thermal expansion that closely matches that of semiconductor materials, ensuring effective heat dissipation while minimizing thermal stress on the chip during operation.

Qorvo's TGA2222D is a wide band power amplifier MMIC fabricated on Qorvo's production 0.15 um GaN on SiC process (QGaN15). The TGA2222D provides 10 W of saturated output power and 16 dB of large-signal gain while achieving greater than 22% power-added efficiency. The TGA2222D employs a balanced architecture to minimize performance sensitivity to load variation. Its RF ports are DC coupled to ground for optimum ESD performance. The TGA2222D has DC blocking capacitors on both RF ports, which are matched to 50 ohms. The TGA2222D can support a variety of operating conditions and a range of bias voltages to best support system requirements. In the illustrated example, to balance power supply and control voltage routing to the TGA2222D, a set of two DC signal traces 118 are connected to one side of the TGA2222D, while a second set of two DC signal traces 118 are connected to an opposing side of the TGA2222D. In each set, one of the two DC signal traces 118 supplies the drain voltage V_{D}, and the other one of the two DC signal traces 118 provides the gate voltage V_{G}. The TGA2222D may also be a bare die surface mounted on a thermal spreader tab. Thermal vias under the thermal spreader tab carries the heat generated from the TGA2222D to the larger ground plane at the backside of the RF board 112. In some embodiments, the thermal spreader tab is made of CuMo.

In RF amplifier circuits, the driver MMIC chip 102, such as the QPA2225D, typically acts as the initial stage. Its primary role is to receive a low-power RF signal input and amplify it to a level suitable for the subsequent stage, which is often a high-power amplifier. While the driver MMIC chip 102 does provide amplification to the signal, its output power generally remains below that of the high-power amplifier stage. A critical function of the driver MMIC chip 102 is to ensure that the signal retains its integrity and shape while also furnishing adequate power for the ensuing amplification stage. Following the driver MMIC chip 102 is the HPA MMIC chip 104, like the TGA2222D, which is the main stage in the RF amplifier chain. The HPA stage's responsibility is to amplify the RF signal to the desired output power level, which is tailored for transmission or other specified application requirements. The HPA MMIC chip 104 is crafted to manage higher power levels in comparison to the driver MMIC chip 102 and delivers the majority of the circuit's amplification. Ensuring the amplifier remains linear and efficient, especially when operating at elevated power levels, is important for the HPA stage.

In the illustrated example, the dimension of the RF board 112 may be about 1 inch in length and about 0.7 inches in width. The cavity height H1, which is a distance from the top surface of the RF board 112 to the lid 110, is about 0.2 inches. The two MMIC chips (e.g., bare dies) 102 and 104 are disposed on opposing sides of the ground plane 116. A distance (length of the RF microstrip line 120b) between the two MMIC chips 102 and 104 is about 0.1 inches. An RF input signal first travels to the driver MMIC chip 102, in this instance, the QPA2225D, where it undergoes preliminary amplification. The signal, now amplified by the driver MMIC chip 102, is relayed to the HPA MMIC chip 104, in this instance, the TGA2222D, where it receives further amplification to reach the targeted power level. The final output from the HPA MMIC chip 104 is then channeled to its designated application, such as for transmission and/or broadcasting. As discussed above with reference to FIGS. 1A and 1B, the MMIC chips 102 and 104 assembled in the package may suffer from significant degradation of output power performance due to the high-level intensity of RF signal interference inside the package housing. Affixing a sheet of RF absorber material to the interior side of the lid 110 may not be sufficient to suppress the high-order modes generated by the cavity formed by the package housing, particularly when the distance between the RF absorber and MMIC chips can hardly be reduced due to the limitation imposed by the cavity height H1.

Still referring to FIGS. 2A and 2B, collectively, the MMIC device 100 further includes the RF absorbing cover 108. The cover 108 is a three-dimensional (3D) cover that includes sidewalls and a top flat surface (also referred to as a lid of the cover) having uniform and continuous RF absorbing material. The two MMIC chips 102 and 104 are housed under the lid of the cover 108.

The cover 108 is made of an RF absorbing material for improving RF signal isolation and suppressing RF cavity modes. The RF absorbing material combines the dielectric properties of a plastic material with the magnetic attributes of ferrite particles. To create this absorber, plastic, often in the form of a polymer matrix, is uniformly mixed with finely dispersed ferrite particles. This composite material not only ensures flexibility and durability but also capitalizes on the ferrite's inherent property to absorb and dissipate RF energy. As the RF waves penetrate the absorber, the ferrite particles absorb the energy, converting it to a minimal amount of heat, thus effectively reducing the reflected RF signals. The precise ratio of plastic to ferrite, as well as the specific type of both components, can be adjusted to tailor the absorber's properties to specific frequency ranges and attenuation levels, ensuring optimal performance for diverse RF environments. In some instances, a volumetric percentage of the ferrite particles in the cover 108 may be larger than about 75%. Having a volumetric percentage of the ferrite particles larger than 75% is not arbitrary, as if the ferrite particles occupy a volumetric percentage less than 75%, the RF absorbing capability of the cover 108 may be compromised.

In furtherance of the embodiments, the plastic material to uniformly infuse with ferrite particles is a high-temperature plastic material with a melting point above 100° C., or 200° C., or even 500° C., depending on application needs, as a temperature near the high-power MMIC chip may become very high during operation. The high-temperature plastic material may be polytetrafluoroethylene (PTFE, also known as Teflon), polyetherimide (PEI, also known as Ultem), polyetheretherketone (PEEK), low-temperature co-fired ceramic (LTCC), or other suitable plastic material, in some instances. The ferrite particles in the cover 108 possess high permeability and a high loss tangent. One candidate ferrite material is hexagonal Ba-based or hexagonal Sr-based ferrites. While the real permittivity (ε′) of M-type hexagonal ferrites is approximately 23, these ferrites typically exhibit a relatively low imaginary permittivity of less than 0.8 across broadband frequencies. The magnetic loss tangent is a more important factor for benchmarking capability of absorbing radiated RF signals. In one instance, the RF absorbing material of the cover 108 possesses a magnetic loss tangent greater than 0.174 (>0.174) across operating frequencies from about 10 GHz to about 40 GHz. Having a magnetic loss tangent value greater than 0.174 is not arbitrary, as if the magnetic loss tangent is less than about 0.174, the cover 108 may not be effective in improving RF signal isolation and suppressing RF cavity modes. Other than ferrite particles, alternative materials like lossy carbon particles or nanotubes can be infused into the high-temperature plastic material for making the cover 108. In another embodiment, the cover 108 may be formed by a resistive thin film.

Further, the fabrication of the 3D shape of the cover 108, the fabrication process may employ the synergy of injection molding techniques with the ferrite particles. To commence this process, ferrite particles are uniformly dispersed into a suitable plastic resin, creating a well-blended compound that marries the moldability of plastic with the RF absorption characteristics of ferrite. Once this mixture attains a consistent texture, it is then introduced into an injection molding machine. Under the influence of high temperature and pressure, the composite material is forced into a 3D mold tailored to the desired absorber shape and dimensions. As the material cools and solidifies within the mold, it adopts the intricate contours and features of the 3D design, effectively forming an RF absorber with spatial geometry.

In the illustrated example, the cover 108 may have a thickness of about 10 mil. Compared with attaching to the lid 110 of the device housing 106, the cover 108 has a low profile and is much closer to the MMIC chips underneath. In the illustrated example, the cover 108 has not direct contact with the device housing 106. The exact height and shape of the cover 108 can be optimized for optimal performance. In some embodiments, a gap between the MMIC chips' surface and the cover 108 ranges from about 0.01 inches to about 0.015 inches. In some embodiments, the height H2 of the cover 108 is approximately between ⅕ and ½ of the cavity height H1.

Since the cover 108 has no direct contact with the device housing 106, the cover 108 may be affixed to the top surface of the RF board 112 through four legs at corners of the cover 108, as shown in FIG. 2A. An adhesive material (e.g., glue or epoxy) may be used to adhere the cover 108 to the exposed dielectric material of the RF board 112. The sidewalls of the cover 108 have openings 130, which allow the RF microstrip lines 120 and DC signal traces 118 to travel through without touching the cover 108. A portion of the sidewalls of the cover 108 between the openings 130 may land on the ground plane 116 with a direct contact therebetween (but without applying an adhesive material). The lid of the cover 108 may have two retreats (or cutouts) above the input port of the MMIC chip 102 and the output port of the MMIC chip 104, respectively. The retreats reduce detuning to the 50 Ohm impedance of the RF microstrip lines 120 and spare room for mounting connectors (e.g., coaxial connectors) on edges of the RF board 112.

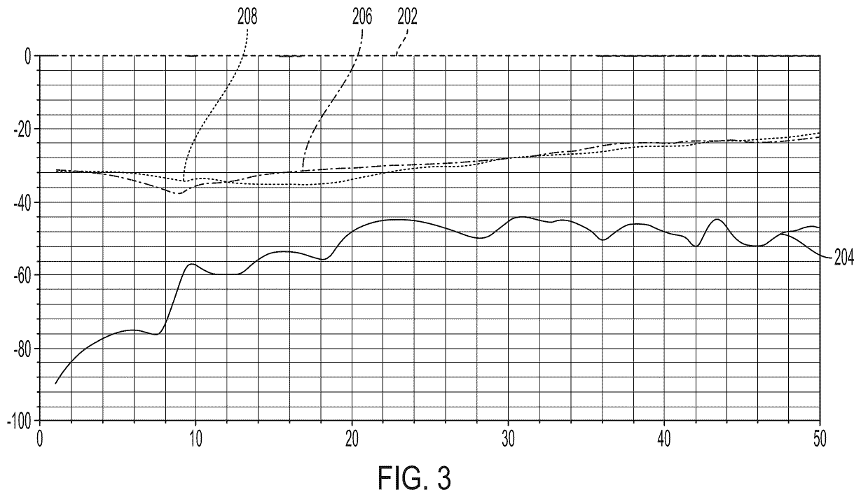

Reference is now made to FIG. 3, which demonstrates the effectiveness of employing the RF absorbing cover 108 in the MMIC device 100. FIG. 3 presents simulated RF passive responses in the MMIC device 100. As depicted above, the MMIC chips 102 and 104 may be separated by approximately 0.1 inches with a 50 Ohm RF microstrip line 120b. The compact assembly generally results in low RF isolation between the two MMIC chips 102 and 104, leading to RF instability. As a comparison, placing an RF absorbing cover 108 atop the two MMIC chips 102 and 104 mitigates RF coupling by absorbing RF signals emitted from each MMIC chip. Additionally, such an RF absorbing cover 108 does not attenuate the RF signal propagating through the RF microstrip lines, which is demonstrated by the trace 202 representing a nearly 0 dB transmission coefficient of the RF microstrip lines 120. On the other hand, the RF absorbing cover 108 effectively attenuates RF signals radiated from the MMIC chips 102 and 104 and other circuit elements within the package, which is demonstrated by a trace 204 representing an isolation between an output port of the MMIC chip 102 and an input port of the MMIC chip 104. From DC to 50 GHz, the trace 204 remains below −40 dB, representing an isolation exceeding 40 dB between the two MMIC chips is achieved over a wide frequency spectrum. Such a high isolation agrees with the trace 206 and trace 208 representing achieving low return losses at input ports of the MMIC chips 102 and 104. The RF responses illustrated in FIG. 3 suggests that the RF absorbing cover 108 can effectively achieve high RF isolation between MMIC chips and maintain robust RF transmission from input to output of the package, making it a viable solution for high RF and mm-wave power modules.

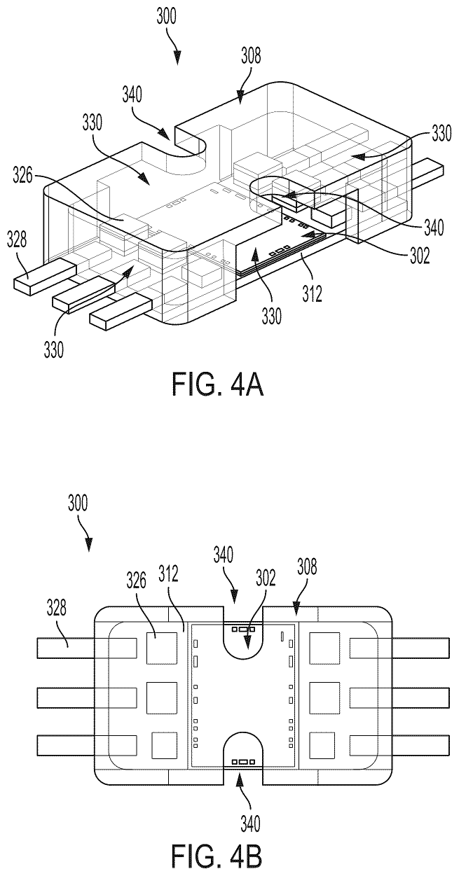

In the depicted instance as shown in FIGS. 2A and 2B, the RF absorbing cover 108 shields multiple MMIC chips thereunder. Similarly, an RF absorbing cover may be deployed to shield a single MMIC chip thereunder, such as depicted in FIGS. 4A and 4B.

Referring to FIGS. 4A and 4B, collectively, FIGS. 4A and 4B illustrate perspective and layout views, respectively, of a packaged single MMIC device 300. The MMIC device 300 includes a single MMIC chip (e.g., a bare die) 302 disposed on an RF board 312. The MMIC chip 302 may be similar to the MMIC chip 102 or the MMIC chip 104. In the illustrated instance, the MMIC chip 302 may be Qorvo's TGS 222D, which is a wide band power amplifier MMIC fabricated on Qorvo's production 0.15 um GaN on SiC process (QGaN15). The RF board 312 may be similar to the RF board 112, such as a low dielectric soft PCB. The MMIC chip 302 may be surface mounted on a thermal spreader tab, such as a CuMo pad, with thermal vias conducting heat to the backside ground plane of the RF board 312. The MMIC device 300 also includes capacitors 326 (three on each side of the MMIC chip 302) surface mounted on the RF board 312. Leads 328 are integrated into the package to allow DC and control signals, such as the drain voltage V_{D} and the gate voltage V_{G}, to enter the package. The leads 328 would be wire bonded to the capacitors 326 and the capacitors 326 would be then wire bonded to the desired pads on the MMIC chip 302.

The RF absorbing cover 308 may be similar to the RF absorbing cover 108, such as comprising a high-temperature plastic material uniformly mixed with ferrite particles, carbon particles, nanotubes, or other suitable RF absorbing materials. The height and thickness of the cover 308 may be tuned to suit the performance needs of the MMIC device 300. The bottom opening of the cover 308 may be designed with a precise contour that the RF board 312 may be snugged in. Accordingly, the cover 308 covers the whole RF board 312, including the MMIC chip 302 and the capacitors 326. The cover 308 also includes openings 330 that allow the leads 328 to travel through. The cutouts 340 in the lid of the cover 308, which are positioned on the opposing sides of the MMIC chip 302, allow for a wire bonding tool to have access to the input and output RF pads on the MMIC chip 302. The MMIC device 300 may also include a metallic device housing (not shown) enclosing the cover 308, while the cover 308 may be at least spaced apart (i.e., no direct contact) from the lid of the metallic device housing.

MMICs have revolutionized high-frequency circuit design by offering a compact, reliable, and efficient means of integrating various microwave functions onto a single chip. Their wide range of applications from consumer electronics to mission-critical military systems attests to their versatility and growing importance in the field of electronics. Advancements in technology are continually pushing the boundaries of MMIC capabilities, with the focus on improving stability, reducing interferences, and increasing power efficiency. An RF absorbing cover, when integrated into an MMIC package, offers significant advantages in enhancing the device's performance. Such an RF absorbing cover improves RF isolation between components, ensuring that each operates without unintended influence from neighboring parts. Additionally, such an RF absorbing cover effectively mitigates RF interferences, reducing the potential for signal degradation or loss. As a result, incorporating an RF absorbing cover provides a viable solution for improving overall reliability and efficiency of MMIC packages, particularly for high-power MMIC modules for mm-wave applications.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A radio frequency (RF) module, comprising:
a circuit board;
at least one integrated circuit disposed on a top surface of the circuit board;
an RF absorbing cover housing the at least one integrated circuit, thereby forming a first cavity between the at least one integrated circuit and the RF absorbing cover; and
a metal lid disposed above the RF absorbing cover, thereby forming a second cavity between the RF absorbing cover and the metal lid.

2. The RF module of claim 1, wherein the RF absorbing cover includes a magnetic loss tangent greater than 0.174.

3. The RF module of claim 1, wherein the RF absorbing cover is free of direct contact with the metal lid.

4. The RF module of claim 1, wherein the RF absorbing cover includes sidewalls and a lid, wherein the sidewalls are in direct contact with the top surface of the circuit board.

5. The RF module of claim 4, wherein the circuit board includes signal traces fed to the at least one integrated circuit, and wherein the sidewalls of the RF absorbing cover included at least one opening for the signal traces to travel through.

6. The RF module of claim 1, wherein the RF absorbing cover includes a plastic material uniformly mixed with ferrite particles.

7. The RF module of claim 6, wherein the plastic material is a high-temperature plastic material with a melting point above 200° C.

8. The RF module of claim 6, wherein the ferrite particles are hexagonal Ba-based or hexagonal SR-based ferrite particles.

9. The RF module of claim 1, wherein the RF absorbing cover houses two monolithic microwave integrated circuit (MMIC) chips.

10. The RF module of claim 1, wherein the second cavity has a larger volume than the first cavity.

11. A monolithic microwave integrated circuit (MMIC) package, comprising:
a circuit board;
a first MMIC bare die surface mounted on the circuit board;
a second MMIC bare die surface mounted on the circuit board;
a three-dimensional (3D) radiation absorbing cover partially enclosing the first and second MMIC bare dies, wherein the radiation absorbing cover is configured to absorb radiation from the first and second MMIC bare dies; and
a device housing including a base and a metal lid, wherein the metal lid is suspended above the radiation absorbing cover.

12. The MMIC package of claim 11, wherein the first and second MMIC bare dies are power amplifying integrated circuits.

13. The MMIC package of claim 11, wherein a magnetic loss tangent of the radiation absorbing cover is greater than 0.174.

14. The MMIC package of claim 11, wherein the radiation absorbing cover includes a plastic material uniformly mixed with a radiation absorbing material.

15. The MMIC package of claim 14, wherein a volumetric percentage of the radiation absorbing material in the radiation absorbing cover is greater than 75%.

16. The MMIC package of claim 14, wherein the radiation absorbing material is selected from the group of ferrite particles, carbon particles, and nanotubes.

17. The MMIC package of claim 11, wherein the radiation absorbing cover has a first height, a ratio of the first height and a distance between the metal lid and the circuit board ranges from ⅕ to ½.

18. An integrated circuit package, comprising:
a circuit board;
a bare die landing on the circuit board;
capacitors landing on the circuit board and coupled to the bare die;
leads attached to the circuit board; and
a radiation absorbing cover enclosing the circuit board and the bare die, wherein the radiation absorbing cover includes sidewall openings for the leads to travel through.

19. The integrated circuit package of claim 18, wherein a magnetic loss tangent of the radiation absorbing cover is greater than 0.174.

20. The integrated circuit package of claim 18, further comprising:
a metal housing enclosing the radiation absorbing cover, wherein the metal housing includes a lid that is spaced apart from the radiation absorbing cover.
